(19) United States
(12) Patent Application Publication
(10) Pub. No.: US 2015/0155399 A1
(43) Pub. Date: Jun. 4, 2015

(54) INTEGRATED BACK SHEET WITH AN ALUMINUM CONDUCTIVE CIRCUIT AND BACK-CONTACT PHOTOVOLTAIC MODULE

(71) Applicant: E I DU PONT DE NEMOURS AND COMPANY, Wilmington, DE (US)

(72) Inventors: Minfang MU, Shanghai (CN); Zelin LIU, Shanghai (CN)

(21) Appl. No.: 14/560,369

(22) Filed: Dec. 4, 2014

(30) Foreign Application Priority Data
Dec. 4, 2013 (CN) 201310642495.3

(51) Int. Cl. H01L 31/0224; H01L 31/048; H01L 31/049

(52) U.S. Cl. CPC H01L 31/02245; H01L 31/022441; H01L 31/049; H01L 31/0481

(57) ABSTRACT

An integrated back sheet with an aluminum conductive circuit and a back-contact photovoltaic module are provided. In the integrated back sheet and the back-contact photovoltaic module, metallic conductive parts are directly welded in a certain pattern onto the front side of the aluminum conductive circuit by ultrasonic welding. Electrical bonding parts connect the metallic conductive parts through an insulation layer to the electric back contacts of a photovoltaic cell. A method of making the integrated back sheet with an aluminum conductive circuit and a back-contact photovoltaic module incorporating the integrated back sheet are also provided.

### FIELD OF THE INVENTION

The present invention relates to an integrated back sheet and a back-contact photovoltaic module, particularly to an integrated back sheet with an aluminum conductive circuit and a back-contact photovoltaic module.

### BACKGROUND OF THE INVENTION

Since photovoltaic (or solar) cells can provide sustainable energy, their application scope is rapidly expanding. In commercialized conventional silicon solar cells, both the emitter region and the emitter electrodes are on the front side of the cell.

When manufacturing a conventional photovoltaic module, in order to achieve weather resistance lasting at least 25 years, photovoltaic cells are typically sandwiched or laminated between polymer encapsulation layers, and the photovoltaic cells are further isolated from the environment by a front panel and a back sheet which also provide mechanical support for the module. Therefore, the front panel and the back sheet are also known as external protective panels.

Generally speaking, a photovoltaic module based on crystalline silicon cells comprises in sequence the following, from the back (not facing the sun) to the front (facing the sun): (1) a back sheet, (2) a back encapsulation layer, (3) photovoltaic cells, (4) a front encapsulation layer, and (5) a front panel.

In the photovoltaic module having the structure as described above, what is important is that the material provided on the sun-facing side (i.e. the front panel such as a glass plate and the front encapsulation layer) of the photovoltaic cell has a high light transmittance to allow sufficient sunlight to reach the photovoltaic cell.

The encapsulation layer (i.e. the front encapsulation layer and the back encapsulation layer) is typically made of a polymer material, such as an acid copolymer, an ionomer, ethylene-vinyl acetate copolymer (EVA), a poly(vinyl acetal) (for example, poly(vinyl butyral) (PVB)), polyurethane, poly(vinyl chloride), a polyethylene (for example, a linear low density polyethylene), a polyolefin block copolymer elastomer, a copolymer of α-olefin and α,β-olefinic bond unsaturated carboxylate (for example, ethylene-methyl acrylate copolymer and ethylene-butyl acrylate copolymer), a silicone elastomer, an epoxy resin, or a combination of two or more of the polymer materials as described above. Among the polymer materials, EVA is the most popular choice for the encapsulation materials for the photovoltaic cell. The front encapsulation layer may be formed of one or more layers of the polymer materials by lamination, and the back encapsulation layer may also be formed of one or more layers of the polymer materials by lamination.

For a commercialized conventional photovoltaic cell, the emitter electrode positioned on the front side of the cell is beneficial for increasing the efficiency of charge carrier collection. However, the structure has the following limitations: although a small area is occupied, the electrode will still block some sunlight, thus decreasing the available sunlight-receiving area of the photovoltaic cell. Additionally, when assembled, a tin-coated strip is required to be welded from the front side of one cell to the back side of another cell, which causes difficulties in automated production. Therefore, some researchers have moved the electrode from the front side to the back side of the cell and have developed many differently structured back-contact photovoltaic cells. A back-contact photovoltaic cell may be a photovoltaic cell with the emitter electrode completely or partially located on the back side of the cell. The back-contact cell has attracted much attention in the market due to its structure, manufacturing process and high efficiency. The back-contact cell has the following advantages: 1) efficient: the efficiency of the cell is increased as the shading loss of the front grating electrode is reduced or completely eliminated; 2) suitable for automatic assembly and production: a new assembly encapsulation mode is employed for coplanar connection, which shortens the distance between the cells, increases the encapsulation density, simplifies the manufacturing process and reduces the encapsulation difficulty; and 3) more aesthetically pleasing: The front side of the back-contact photovoltaic cell is even and aesthetically pleasing, thus meeting the aesthetic requirements of consumers.

In a back-contact photovoltaic cell, because the electrode is moved from the front side to the back side of the cell, the coverage area of the silver paste on the front sunlight-receiving side of the cell is decreased and thus the efficiency of the back-contact photovoltaic cell is increased.

At present, drawbacks of back-contact photovoltaic cells and modules include their complex manufacturing process and high cost. FIG. 1 is a schematic sectional view of a known back-contact photovoltaic module 1000. As shown in FIG. 1, in a sequence from the back (not facing the sun) to the front (facing the sun), the back-contact photovoltaic module 1000 comprises the following: a back sheet (or back panel or substrate) 1010, a metallic conductive circuit (for example, a copper conductive circuit) 1011 arranged on the back sheet, a back insulation layer (or back encapsulation layer) 1020, a back-contact photovoltaic cell 1030, a front encapsulation layer 1040 and a front panel 1050. As shown in FIG. 1, a plurality of electric contacts 1031 aligned with a plurality of through holes of the back insulation layer 1020 are formed on the back side of the back-contact photovoltaic cell 1030; the back-contact photovoltaic cell 1030 is also provided with a plurality of electrode guiding holes 1032 extending from the front side to the back side of the cell. The conductive paste guides the electrode from the front side of the back-contact photovoltaic cell 1030 to the back side through the electrode guiding holes 1032 to form the electric contacts 1031 on the back side of the back-contact photovoltaic cell 1030. The electrical connection between the electric contacts 1031 on the back side of the back-contact photovoltaic cell 1030 and the metallic conductive circuit 1011 is provided by a conductive material (for example, a conductive adhesive) filled in the plurality of through holes of the back insulation layer 1020.

The metallic conductive circuit of a back-contact photovoltaic module is typically made of copper or a copper alloy. However, the cost of copper is relatively high, and it is desirable to replace copper with other less expensive metals to serve as the material of the metallic conductive circuit to lower the production cost of a back-contact photovoltaic module. Aluminum conductive circuits and an integrated back sheet with an aluminum conductive circuit have been reported in the literature. However, in practical applications, the surface of aluminum or an aluminum alloy is liable to be oxidized in air to form a non-conductive oxide film (Al₂O₃), which will result in an extremely high contact resistance between the aluminum or aluminum alloy and other conductive materials (for example, a conductive adhesive), which ultimately leads to low module efficiency or even failure of a module so prepared. For instance, FIG. 2 is a scanning electron micrograph of an aluminum foil covered completely by an Al₂O₃ film. As clearly illustrated in FIG. 2, a layer of continuous and dense Al₂O₃ film A is formed on the surface of the aluminum foil substrate, and the Al₂O₃ film A isolates the aluminum foil substrate from the ambient. Therefore, some problems still exist in the use of an aluminum conductive circuit in a back-contact photovoltaic module, which impose significant restrictions on the use of the same.

Therefore, manufacturers of back-contact photovoltaic modules are in need of a method for manufacturing an integrated back sheet for a back-contact photovoltaic module with excellent cell performance, low cost and low consumption of conductive adhesive and copper, a method for manufacturing the back-contact photovoltaic module, and such an integrated back sheet and back-contact photovoltaic module.

### SUMMARY OF THE INVENTION

An integrated back sheet with an aluminum conductive circuit is provided for a back-contact photovoltaic module in order to replace an integrated back sheet with a copper conductive circuit. However, due to easy oxidization of the surface of the aluminum plate, which decreases the efficiency of integrated back sheet with an aluminum conductive circuit, it is necessary to treat or protect the aluminum plate during manufacturing.

The present invention successfully solves the problems in the prior art by employing ultrasonic welding, specifically, conducting ultrasonic welding with a frequency of 10-50 kHz and an amplitude of 8-50 μm to break the continuous and dense oxide film on the surface of the aluminum conductive circuit and connect a metallic conductive part directly to the aluminum conductive circuit at the same time. In the welding process, the welded device will be subjected to an action of a welding thermal process, a metallurgical reaction, and/or welding stress and deformation, which results in a change of chemical composition and metallographic structure near the welded portion. Particularly, when high energy is applied to the aluminum conductive circuit by ultrasonic welding, the continuous Al₂O₃ film (see FIG. 2) on the surface of the aluminum conductive circuit can be broken and scattered to form a dispersed phase B (please see FIG. 3), such that a fresh aluminum surface is exposed and the metallic conductive part can be connected directly to the fresh aluminum surface. With this connecting structure, the fresh aluminum surface is protected from oxidization, thereby realizing an effective electrical connection with low resistivity.

The embodiment employs the aluminum conductive circuit with Al₂O₃ film on the surface to substitute for the more expensive copper conductive circuit of known back-contact photovoltaic modules, thereby realizing an inexpensive and applicable integrated back sheet with an aluminum conductive circuit. Further, the present invention employs ultrasonic welding with a frequency of 10-50 kHz and an amplitude of 8-50 μm to break the continuous Al₂O₃ film which severely hinders the electrical conductivity on the surface of the aluminum plate (see FIG. 2 and FIG. 3, wherein FIG. 3 is an electron micrograph of a nickel-clad copper and an aluminum conductive circuit connected to each other by ultrasonic welding), thus reducing the resistance of the contact surface of aluminum with other metals, and greatly improving the conductivity.

The back-contact photovoltaic module with an aluminum conductive circuit manufactured by the method provided by the present invention is not only capable of realizing the output power comparable to that of a back-contact photovoltaic module with a copper conductive circuit, but it also capable of greatly reducing the consumption of conductive adhesive and copper, thus greatly lowering the production cost.

Particularly, the present invention involves the following aspects:

1. An integrated back sheet with an aluminum conductive circuit for a back-contact photovoltaic module, comprising in sequence the following from the back side to the front side of the integrated back sheet:

a substrate having a back side and a front side opposite to one another;

an aluminum conductive circuit provided on the front side of the substrate, the aluminum conductive circuit having a back side adjacent to the substrate and a front side facing away from the substrate; and

a back insulation layer adjacent to the aluminum conductive circuit, the back insulation layer having a back side adjacent to the aluminum conductive circuit and a front side facing away from the aluminum conductive circuit, the back insulation layer being provided with a plurality of through holes extending from the back side to the front side of the back insulation layer, and aligned with the conductive circuit;

wherein, each through hole is filled with a combined conductive component comprising an electrical bonding part and a conductive part complementary to the electrical bonding part in shape; the electrical bonding part being adjacent to the front side of the back insulation layer; the conductive part being made of one or more metallic materials and being welded on the front side of the aluminum conductive circuit by ultrasonic welding at a frequency of 10-50 kHz and an amplitude of 8-50 μm; and wherein the contact area of the conductive part with the front side of the aluminum conductive circuit is 3-20 mm²; and

when the integrated back sheet is applied in manufacture of the back-contact photovoltaic module, the electrical bonding part of the combined conductive component is attached to an electric contact on the back side of a back-contact photovoltaic cell.

2. The integrated back sheet according to aspect 1, characterized in that the one or more metallic materials are selected from the group of substance consisting of copper, tin, nickel, titanium, silver-plated copper, nickel-clad copper, copper-clad aluminum, tinned copper, gold-plated nickel, stainless steel, and alloys thereof, and combinations thereof.

3. The integrated back sheet according to aspect 1, characterized in that the conductive part of the combined conductive component accounts for 3-95% of the total volume of the combined conductive component.

4. The integrated back sheet according to aspect 1, characterized in that the electrical bonding part is made of a conductive material comprising at least 5% (volume percentage) of a polymer material.

5. The integrated back sheet according to aspect 4, characterized in that the electrical bonding part is made of a conductive polymer material.

6. The integrated back sheet according to aspect 4, characterized in that the electrical bonding part is made of a conductive adhesive comprising a polymer material and conductive particles dispersed in the polymer material.

7. The integrated back sheet according to aspect 6, characterized in that the conductive particles are selected from the group consisting of gold, silver, nickel, copper, aluminum, tin, zinc, titanium, bismuth, tungsten, lead, and alloys thereof.

8. The integrated back sheet according to aspect 1, characterized in that the back insulation layer comprises one or more layers of a polymer film or plate.

9. The integrated back sheet according to aspect 8, characterized in that at least one layer of the back insulation layer is made of a polymer composition comprising ethylene-vinyl acetate copolymer (EVA), an ionomer or a poly(vinyl butyral) (PVB).

10. The integrated back sheet according to aspect 1, characterized in that the thickness of the aluminum conductive circuit is 30-250 μm.

11. A back-contact photovoltaic module comprising in sequence the following from the back to the front of the back-contact photovoltaic module:

the integrated back sheet with an aluminum conductive circuit according to any one of the aspects of 1 to 10;

a back-contact photovoltaic cell having a front sunlight receiving side and a back side opposite to one another, wherein a plurality of electric contacts are formed on the back side of the back-contact photovoltaic cell, the back side of the back-contact photovoltaic cell is adjacent to the back insulation layer of the integrated back sheet, and the plurality of electric contacts on the back side of the back-contact photovoltaic cell are aligned with the plurality of through holes of the back insulation layer and connected with the electrical bonding parts in the through holes;

a front encapsulation layer adjacent to the front side of the back-contact photovoltaic cell; and

a transparent front panel adjacent to the front encapsulation layer.

12. The back-contact photovoltaic module according to aspect 11, characterized in that the back-contact photovoltaic cell is a metal wrap through (MWT) type photovoltaic cell.

The present invention has the following advantages:

The technical solution of the present invention meets a need of manufacturers for a back-contact photovoltaic module. The back-contact photovoltaic module with an aluminum conductive circuit manufactured by the method provided by the present invention is not only capable of realizing the output power comparable to that of the back-contact photovoltaic module with a copper conductive circuit, but also capable of greatly reducing the consumption of conductive adhesive and copper, thus greatly lowering the production cost of the module and realizing considerable cost effectiveness.

The advantages and new features of the present invention are particularly defined in the accompanying claims which constitute a part of this application. However, to better understand the present invention and the advantages thereof as well as the objectives to be achieved by the use of the present invention, one should refer to the figures, which constitute another part of this application, and the following descriptive matters, wherein one or more preferred embodiments are illustrated and described.

### BRIEF DESCRIPTION OF THE DRAWINGS

The present invention will be described in detail with reference to the figures. The figures may not be drawn strictly to scale, and are merely schematic representations. In the figures of the application, the same or similar reference numbers represent the same or similar elements.

FIG. 1 is a schematic sectional view of a prior art back-contact photovoltaic module 1000 showing in detail the conductive material used for providing an electrical connection between the electric contact on the back side of a back-contact photovoltaic cell and a copper conductive circuit.

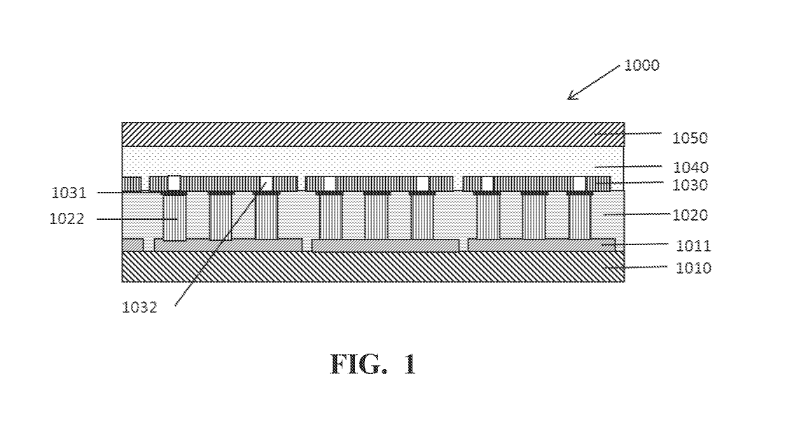

FIG. 2 is a scanning electron micrograph of an aluminum foil fully covered by an Al₂O₃ film.

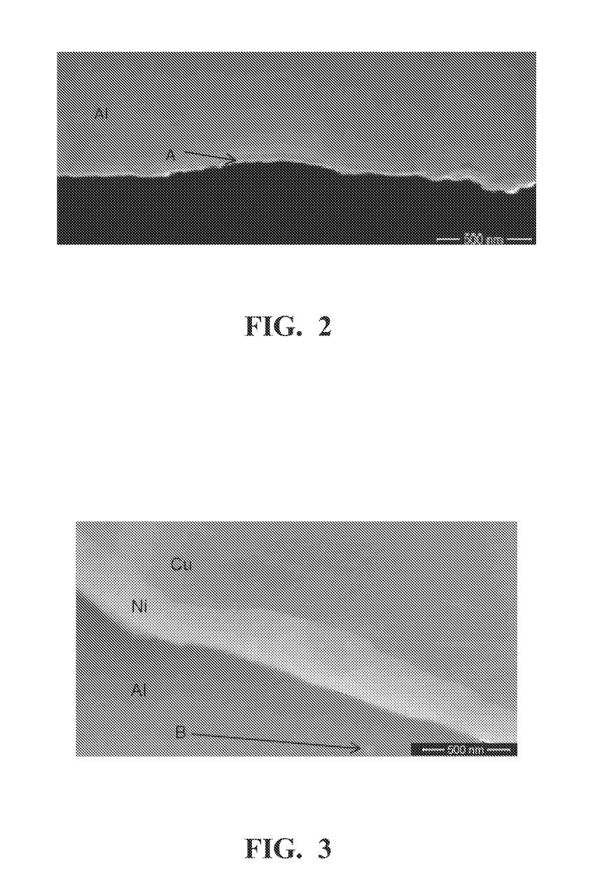

FIG. 3 is an electron micrograph of a nickel-clad copper and an aluminum conductive circuit connected with each other by ultrasonic welding.

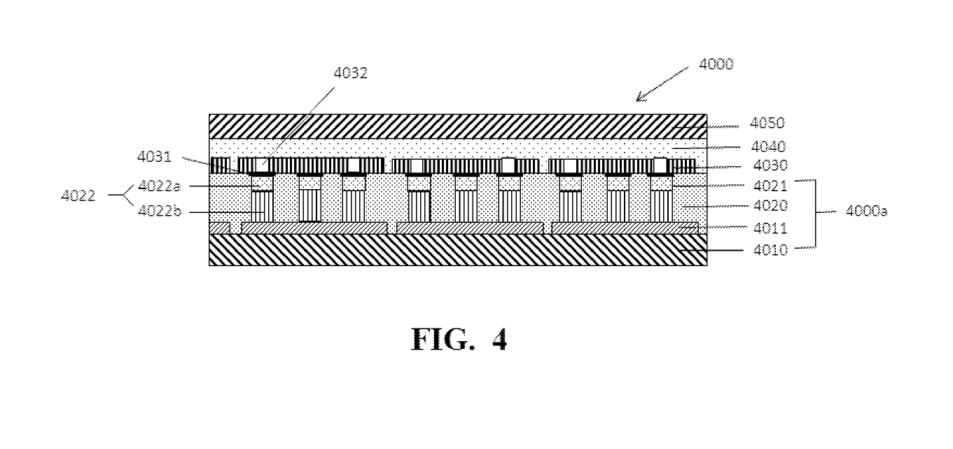

FIG. 4 is a schematic sectional view of the back-contact photovoltaic module with a combined conductive component.

FIGS. 5a to FIG. 5g are schematic flow diagrams of the disclosed method for manufacturing the integrated back sheet with an aluminum conductive circuit for a back-contact photovoltaic module.

### LIST OF PARTS AND REFERENCE NUMBERS IN THE FIGURES

| | |
|---|---|
| 1000 | Back-contact Photovoltaic Module |
| 1010 | Substrate |
| 1011 | Metallic Conductive Circuit |
| 1020 | Back Insulation Layer |
| 1022 | Conductive Material |
| 1030 | Back-contact Photovoltaic Cell |
| 1031 | Electric Contact |
| 1032 | Electrode Guiding hole |
| 1040 | Front Encapsulation Layer |
| 1050 | Front Panel |
| 4000 | Back-contact Photovoltaic Module |
| 4000a | Integrated Back Sheet with an Aluminum |
| | Conductive Circuit |
| 4001 | Aluminum Plate (Aluminum Foil) |
| 4010 | Substrate |
| 4011 | Aluminum Conductive Circuit |
| 4020 | Back Insulation Layer |
| 4021 | Through Hole |
| 4022 | Combined Conductive Component |
| 4022a | Electrical Bonding Part |
| 4022b | Conductive Part |
| 4030 | Back-contact Photovoltaic Cell |
| 4031 | Electric Contact |
| 4032 | Electrode Guiding hole |
| 4040 | Front Encapsulation Layer |
| 4050 | Front Panel |
| A | Continuous Al₂O₃ Film |
| B | Dispersed Phase |

### DETAILED DESCRIPTION OF THE INVENTION

Unless other restrictions for special cases are stated, the following definitions are applicable to the terms in the Description.

Unless otherwise specified, the meanings of all the technical terms used herein are the same as the general understandings of a person skilled in the art. In case of contradiction, the Description and definitions used herein shall prevail.

Although any method and material similar or equivalent to the method and material described herein may be applicable to practice or inspection of the present invention, appropriate methods and materials are described herein.

Some terms used herein are defined as follows:

As used herein, “aluminum conductive circuit” or “aluminum circuit” refers to a conductive circuit made of aluminum or an aluminum alloy. Aluminum alloy is a generic term for an aluminum-based alloy, i.e. an alloying material which is based on aluminum with addition of one or more alloy elements. In a conductive aluminum alloy, the content of aluminum is 90 wt % or higher, 95 wt % or higher, or 97 wt % or higher; the predominate non-aluminum alloy elements include but are not limited to copper, silicon, magnesium, zinc or manganese; and the secondary non-aluminum alloy elements include but are not limited to nickel, ferric, titanium, chromium, boron, lithium, and the like.

As used herein, directional terms such as “on” and “under” are consistent with particular directions as shown in the figures.

As used herein, directional terms such as “front”, “back”, “front side” and “back side” are consistent with the general descriptions of the back-contact photovoltaic module in the art.

As used herein, “about” refers to that the number, size, formulation, parameter and other amounts and properties, are imprecise and not required to be precise, but may be approximate to and/or larger than or smaller than the precise value, thus reflecting the tolerances, conversion factors, rounding off for values, measurement errors and other factors known by a person skilled in the art. Generally speaking, the number, size, formulation, parameter or other amounts or properties are described as “about” or “approximate” regardless of whether they are so explicitly described or not.

In addition, unless otherwise clearly specified in very rare cases, the range as cited in the present invention includes the end points of the range. In addition, when an amount, concentration or other values or parameters are described in the form of a range, one or more preferred ranges or a preferred upper limit and a preferred lower limit, it should be understood as it discloses specifically all the ranges consisting of any upper limit or preferred value and any lower limit or preferred value regardless of whether the range is disclosed independently or not.

Furthermore, unless otherwise clearly specified, for any number range listed herein, the range includes the end points as well as all the integers and decimals within the range. The definition of a range is not intended to limit the scope of the present invention to any particular values listed. Where the term “about” is used to describe a value or the end points of a range, the content of this disclosure should be understood as including the particular value and the relevant end points.

As used herein, where a material, a method or a mechanical device is described with “known by a person skilled in the art” or synonymous words or phrases, it means that the material, method or mechanical device is included in this description when the present patent application is filed. Any material, method and mechanical device which are unconventional at present but will be commonly recognized as conventional when applied for similar purposes, are also covered by this description.

As used herein, terms “include”, “contain”, “comprise” “cover”, “characterized in that”, “have” or any other synonymous words or any other variants thereof refer to non-exclusive inclusion. For instance, the process, method, article or device comprising particular elements is not necessarily limited merely to the elements listed, but may comprise other elements not listed clearly or the elements inherent to the process, method, article or device.

The transitional phrase “consist essentially of . . . ” defines the scope of a claim to the specified materials or steps and those materials or steps which would not impose a substantial impact on the basic features or new features of the claimed invention. A claim using “consist(s) essentially of . . . ” covers a scope between the scope covered by a close-type claim written in the form of “consist(s) of . . . ” and an open-type claim written in the form of “contain(s)/comprise(s)”.

Unless otherwise clearly specified, where Applicant describes the present invention or a part thereof with an open-type term, such as “include”, it should be understood that the description would also cover the description using the term “consist(s) essentially of . . . ” as defined above.

The quantifier “one” or “a/an” is used to describe an element or a component of the present invention. The use of such quantifiers is intended to indicate existence of one or at least one such element or component. The quantifier is generally applied to modify a singular noun; however, unless otherwise clearly specified, the quantifier “one” or “a/an” used herein also covers the plural meaning.

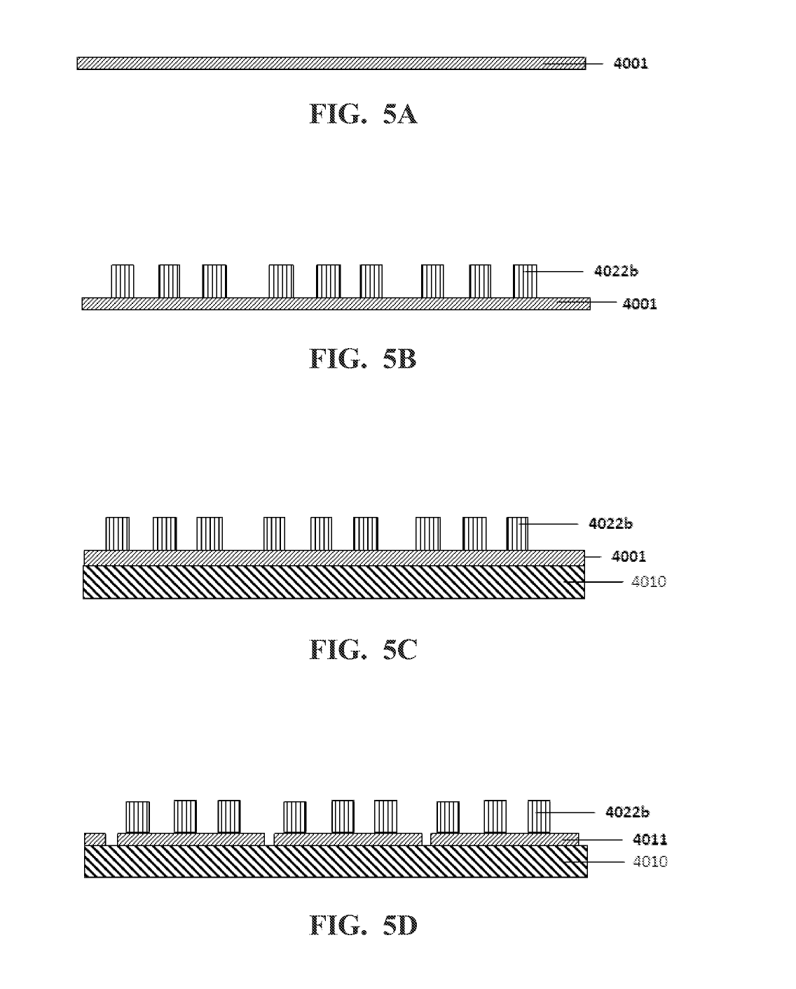

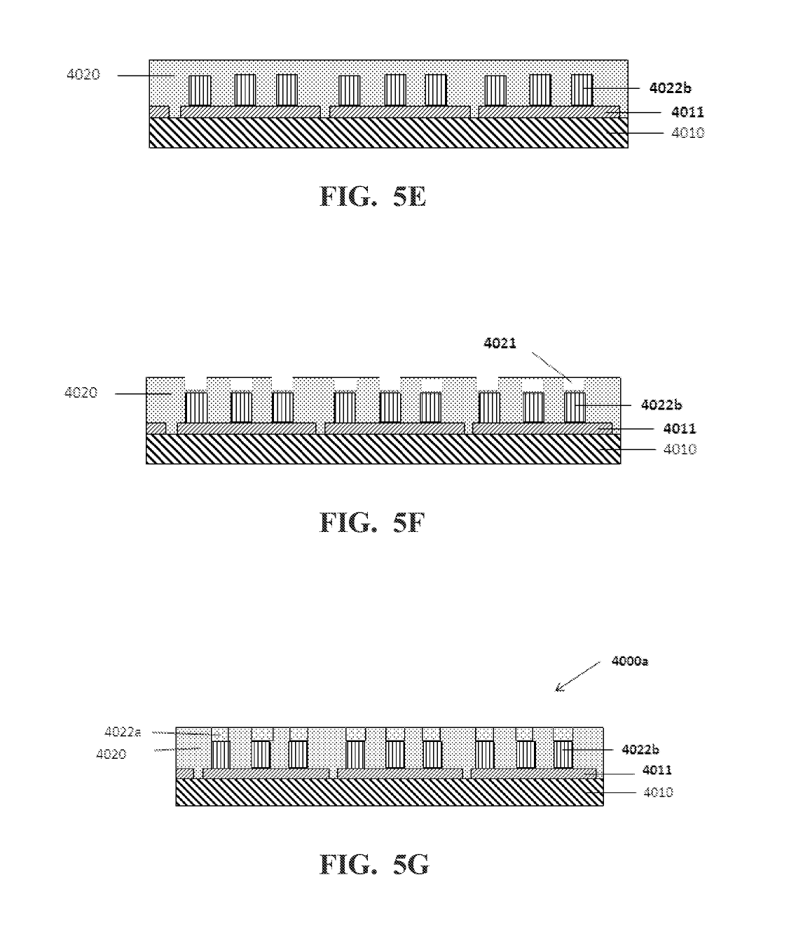

As used herein, the term “back-contact photovoltaic module” refers to a finished functional device having a multilayer laminated structure as shown in FIG. 4, for example; the term “integrated back sheet” refers to a multilayer semi-finished assembly (please see reference number 4000a in FIG. 5G for example) formed during the laminating process for manufacturing the back-contact photovoltaic module; and the term “back-contact photovoltaic cell” refers to a core functional component for converting light energy into electric energy in the back-contact photovoltaic module.

In addition, the term “back insulation layer” refers to one or more layers of a polymer film or sheet located between the conductive circuit and the back-contact photovoltaic cell in the back-contact photovoltaic module for encapsulation and/or insulation.

The term “copolymer” refers to a polymer containing copolymerization units or residues generated via copolymerization of two or more comonomers. In this context, the copolymer may be described with the comonomer components or the amounts of the comonomer components. For instance, “the copolymer comprises ethylene and 9% (weight percentage) of acrylic acid” or a similar description may be employed to describe the copolymer. Since the comonomer is not regarded as the copolymerization unit, and it does not have a conventional nomenclature of copolymer such as a nomenclature of International Union of Pure and Applied Chemistry (IUPAC), and it does not use a method to define an article terms or for other reasons, the description may be deemed to be informal. However, as used herein, the copolymer described with the comonomer components or the amount of the comonomer components refers to that the copolymer contains the copolymerization unit of the particular comonomer (which is in a specified amount when specified). Consequently, unless otherwise clearly specified in limited cases, the copolymer is not the product containing a reaction mixture of given comonomers in given amounts.

The term “acid copolymer” refers to a polymer containing copolymerization units of α-olefin and α,β-olefinic bond unsaturated carboxylic acid and optionally any other appropriate comonomers (for example, α,β-olefinic bond unsaturated carboxylates).

The term “ionomer” refers to a polymer prepared by partial or complete neutralization of the acid copolymer as described above. More particularly, the ionomer contains ion groups which are metal ion carboxylates, such as base metal carboxylates, alkaline earth metal carboxylates, transitional metal carboxylates and mixtures of such carboxylates. As defined herein, the polymer is typically prepared by partial or complete neutralization (such as reaction with alkali) of the carboxyl group of a precursor or a parent polymer, wherein the precursor or the parent polymer is an acid copolymer. The base metal ionomer used herein is a sodium ionomer (or an ionomer neutralized by sodium), such as a copolymer of ethylene and methacrylic acid wherein the whole or part of the carboxyl groups of the copolymerized methacrylic acid units are in the form of sodium carboxylate.

As used herein independently or in a combination form (for example, “laminated” or “lamination”), the term “laminated body” refers to a structure having at least two layers adhered or attached to each other firmly. These layers may be directly or indirectly adhered to each other. “Directly” means there is no additional material such as an interlayer or an adhesive layer between the two layers, and “indirectly” means that an additional material is provided between the two layers.

Unless otherwise specified, the materials, methods and embodiment as described herein are merely exemplary rather than for limiting scope.

Unless otherwise specified in examples, the percentage and part as described herein are percentage by weight and part by weight.

In the following paragraphs, various embodiments of the present invention will be described in detail with reference to the figures.

FIG. 4 is a schematic sectional view of the back-contact photovoltaic module 4000 comprising the aluminum conductive circuit of the present invention. The back-contact photovoltaic module 4000 is formed by lamination of a plurality of layers. As shown in FIG. 4, the back-contact photovoltaic module 4000 comprises in sequence the following layers from the back (not facing the sun) to the front (facing the sun): a substrate 4010, an aluminum conductive circuit 4011 provided on the substrate 4010, a back insulation layer 4020 provided with a plurality of through holes 4021, a back-contact photovoltaic cell 4030, a front encapsulation layer 4040 and a front panel 4050, wherein each layer has a front side (facing the sun) and a back side (not facing the sun). The back-contact photovoltaic cell 4030 has a front sunlight receiving side (the upper side of the back-contact photovoltaic cell 4030 as shown in FIG. 4) and a back side (the lower side of the back-contact photovoltaic cell 4030 as shown in FIG. 4) opposite to one another, and a plurality of electric contacts 4031 formed on the back side of the back-contact photovoltaic cell 4030. The back side of the back-contact photovoltaic cell 4030 is adjacent to the back insulation layer 4020, and the electric contacts 4031 on the back side of the back-contact photovoltaic cell 4030 are aligned with the through holes 4021 of the back insulation layer 4020. Each through hole 4021 is filled with a combined conductive component 4022. The combined conductive component 4022 comprises an electrical bonding part 4022a and a conductive part 4022b which is in the through hole 4021 and complementary to the electrical bonding part in shape. In the back-contact photovoltaic module 4000, the electrical bonding part 4022a is attached to the electric contacts 4031, and the conductive part 4022b is made of one or more metallic materials and welded onto the front side of the aluminum conductive circuit 4011 by ultrasonic welding at a frequency of 10-50 kHz and an amplitude of 8-50 μm. In addition, the contact area of each conductive part 4022b with the front side of the aluminum conductive circuit 4011 is 3-20 mm². Therefore, by the combined conductive component 4022, an electrical connection between the electric contacts 4031 on the back side of the back-contact photovoltaic cell 4030 and the aluminum conductive circuit 4011 is realized.

Preferably, the front panel 4050 such as a glass plate and the front encapsulation layer 4040 of the back-contact photovoltaic module 4000 are of a high light transmittance to allow sufficient sunlight to reach the back-contact photovoltaic cell 4030. In the back-contact photovoltaic module 4000 as shown in FIG. 4, both the front panel 4050 and the front encapsulation layer 4040 are transparent. The front encapsulation layer 4040 and the back insulation layer 4020 are made respectively of a polymer material such as ethylene-vinyl acetate copolymer (EVA). The front encapsulation layer 4040 and the back insulation layer 4020 are respectively formed respectively of one or more layers of the polymer material (a polymer film or plate) by lamination. Particularly, the material for forming the front encapsulation layer 4040 and/or the back insulation layer 4020 may be selected from a composition comprising ethylene-vinyl acetate copolymer (EVA), an ionomer or poly(vinyl butyral) (PVB). The back insulation layer 4020 may be of a monolayer or multilayer structure, which plays a role of encapsulation of the cell and realizing electrical insulation between the cell and the aluminum conductive circuit. Preferably, at least one layer of a back insulation layer formed by lamination of the multilayer polymer material is made of a polymer composition comprising ethylene-vinyl acetate copolymer, an ionomer or poly(vinyl butyral).

Preferably, the thickness of the aluminum conductive circuit 4011 is 30-250 μm. Preferably, the back-contact photovoltaic cell 4030 in the back-contact photovoltaic module 4000 is a MWT type photovoltaic cell.

In the combined conductive component 4022, the electrical bonding part 4022a may be made of a conductive adhesive, a conductive polymer material or a solder. The conductive adhesive comprises a polymer material and conductive particles dispersed in the polymer material. The conductive particles are selected from the group consisting of gold, silver, nickel, copper, aluminum, tin, zinc, titanium, bismuth, tungsten, lead, and alloys thereof. For instance, the electrical bonding part 4022a may be made of a conductive material comprising at least 5% (volume percentage) of a polymer material. The conductive part 4022b may be made of one or more metallic materials selected from the group of copper, aluminum, tungsten, tin, nickel, titanium, silver-plated copper, nickel-clad copper, tinned copper, copper-clad aluminum, tinned aluminum, gold-plated nickel, stainless steel, and alloys thereof, and combinations thereof. In the combined conductive component 4022, the conductive part 4022b may account for 3-95% of the total volume of the combined conductive component 4022.

In the back-contact photovoltaic module 4000, parts other than the back-contact photovoltaic cell 4030, the front encapsulation layer 4040 and the front panel 4050, may be produced as a unit. The unit here is called “integrated back sheet” or “integrated back sheet with an aluminum conductive circuit” (as for example as shown in FIG. 5G) by a person skilled in the art. The production of the unit of the integrated back sheet 4000a with an aluminum conductive circuit 4011 is beneficial to the manufacture of the back-contact photovoltaic module 4000.

FIG. 5G is a schematic sectional view of the laminated structure of the integrated back sheet 4000a with the aluminum conductive circuit 4011. The integrated back sheet with the aluminum conductive circuit comprises in sequence the following from the back to the front: the substrate 4010 having a back side and a front side opposite to one another; the aluminum conductive circuit 4011 provided on the substrate 4010; the back insulation layer 4020 adjacent to the aluminum conductive circuit 4011 which has the back side adjacent to the aluminum conductive circuit 4011 and the front side facing away from the aluminum conductive circuit 4011, and provided with the through holes 4021 extending from the back side to the front side of the insulation layer, wherein the through holes 4021 are aligned with the aluminum conductive circuit 4011. The through hole 4021 is filled with the combined conductive component 4022 which comprises the electrical bonding part 4022a and the conductive part 4022b complementary to the electrical bonding part 4022a in shape. The conductive part 4022b is formed of one or more metallic materials and directly welded onto the front side of the aluminum conductive circuit 4011 by ultrasonic welding with a frequency of 10-50 kHz and an amplitude of 8-50 μm. In addition, the contact area of each conductive part 4022b with the front side of the aluminum conductive circuit 4011 is 3-20 mm². When the integrated back sheet 4000a is used in the manufacture of the back-contact photovoltaic module 4000, the electrical bonding part 4022a of the combined conductive component 4022 is attached adhesively to the electric contact 4031 on the back side of the back-contact photovoltaic cell.

Metal welding includes liquid welding and solid welding. Metal welding refers to forming an atom bonding on the interface of two metallic parts made of different or the same metals or metal alloys by heating, or applying a pressure, or both, thus realizing an intermetallic connection. In some circumstances, a third metal or metal alloy may be applied onto the interface of two metallic parts to serve as a solder to form respectively an atom bonding with each of the two metallic parts, thus realizing an intermetallic connection.

Generally speaking, liquid welding requires that the welding temperature is higher than the melting point of one or more of the two metallic parts to be welded and the solder. In liquid welding, on the welding interface, one or more of the two metallic parts and the solder will form a molten metal layer, and then a metallic connection of the two metallic parts is realized after it is cooled and solidified. A component produced by liquid welding has the following features: before the liquid welding is performed, an oxide film removal treatment (for example, acid washing or mechanical scraping) and/or anti-oxidation treatment is required for the surfaces of the connected metallic parts to be welded. As such, the welded metallic connection interface is made free of metal oxides. For the aluminum conductive circuit used in the present invention, aluminum and aluminum alloy are liable to form an oxide in air, and the oxide will be formed in the high temperature welding. Therefore, liquid welding is not able to realize a metallic connection between an aluminum or aluminum alloy article and another metallic part even if the oxide film is removed before the welding.

The ultrasonic welding applied in the present invention is a solid welding. Solid welding typically includes ultrasonic welding, diffusion welding, friction welding, explosion welding, hot pressure welding and forge welding. For solid welding, the welding temperature is not required to be higher than the melting point of any one of the two metallic parts and the solder, and the surface unevenness of the metallic parts to be connected is solved completely by a physical approach. For explosion welding, the oxides and other contaminants on the surfaces of the metallic part will be taken away due to the action of high temperature and high speed air flow of explosion, such that the interface between the metallic parts connected by explosion welding is free of oxides. With respect to friction welding, hot pressure welding and forge welding, because a high pressure is applied in the welding process, one or two of the metallic parts to be connected by such methods would be deformed. With respect to ultrasonic welding and diffusion welding, the surfaces of the metallic parts to be connected do not need to be subjected to oxide film removal and/or an anti-oxidation treatment before the welding, and accordingly, scattered and discontinuous metal oxides would still exist at the connection interface of the metallic parts after they are connected by ultrasonic welding or diffusion welding. The difference between the ultrasonic welding and the diffusion welding is that the diffusion welding is conducted at a high temperature and a high pressure for a relatively long period of time. Interdiffusion of the atoms of the two metallic parts connected by diffusion welding occurs therebetween, and an intergranular phase may be formed, while the interface between the metallic parts connected by ultrasonic welding is free of any intergranular phase.

In addition to ultrasonic welding, solid welding also includes diffusion welding, friction welding, explosion welding and forge welding. In comparison with other solid welding approaches, ultrasonic welding is more appropriate for the welding of metallic films, particularly for metallic films with a thickness of 10 μm to 3 mm. Ultrasonic welding has its own unique advantages: the two welded parts will not be compressed or deformed due to absence of a liquid phase or a high pressure; meanwhile, before the ultrasonic welding, the surface of the metal is not required to be washed due to the fact that a continuous phase of oxide and/or contaminant on the surface of the metal is liable to be destroyed and scattered into the welded parts as the ultrasonic welding is conducted, thus ensuring a low resistance of the connection interface of the metallic parts. However, other welding approaches are unable to achieve the effect as described above. For instance, with respect to diffusion welding, interdiffusion of the atoms occurs on the interface of the two welded parts at high temperature and high pressure to form connection. Due to the high temperature, the surfaces of the two welded parts have more metal oxides than the surfaces of the parts not welded, and when two different metals are welded, intermetallic phase would be present on the connection interface. For other solid welding approaches, such as forge welding, an extremely high pressure may be required, which would result in a serious deformation at the welded locations, or a local liquid phase may be required to be introduced in the welding process, which would also result in a local deformation at the welded locations, such as with friction welding.

Therefore, with respect to the integrated back sheet 4000a with the aluminum conductive circuit 4011 of the disclosed embodiment, because the metallic connection between the conductive part 4022b and the aluminum conductive circuit 4011 is realized by ultrasonic welding, the joint of the conductive part 4022b and the aluminum conductive circuit 4011 has the following three features: (1) oxygen is present on the interface of the aluminum conductive circuit 4011 and the conductive part 4022b or within a region of the aluminum conductive circuit 4011 which is less than 10 μm from the interface; (2) on the connection interface of the aluminum conductive circuit 4011 and the conductive part 4022b, the deformation of the aluminum conductive circuit 4011 in the direction perpendicular to the welding interface is less than 10%; and (3) interdiffusion of atoms does not exist at the connection interface of the aluminum conductive circuit 4011 and the conductive part 4022b. Therefore, an effective electrical connection is realized between the conductive part 4022b and the aluminum conductive circuit 4011. These features may be confirmed through analysis using the following method. For instance, ion beam cutting may be applied in the direction perpendicular to the interface of the conductive part 4022b and the aluminum conductive circuit 4011 to acquire a cross section perpendicular to the connection interface, and then an analysis is conducted with X-ray spectrum under a scanning electron microscope. If the connection between the conductive part 4022b and the aluminum conductive circuit 4011 is realized by ultrasonic welding, existence of oxygen in the conductive part 4022b or the aluminum conductive circuit 4011 within a region which is less than 10 μm from the interface can be detected, and the region in the aluminum conductive circuit 4011 (or conductive part 4022b) adjacent to the connection interface is free of the elements constituting the connected conductive part 4022b (or the aluminum conductive circuit 4011). In addition, mechanical polishing may be applied to acquire a cross section perpendicular to the interface of the conductive part 4022b and the aluminum conductive circuit 4011, and a scanning electron microscope is applied to measure the variation in thickness of the region of the aluminum conductive circuit 4011 that is connected with the conductive part 4022b from that of the region that is not connected with the conductive part 4022b. If the connection between the conductive part 4022b and the aluminum conductive circuit 4011 is realized by ultrasonic welding, the variation in thickness will not exceed 10%.

The integrated back sheet 4000a with the aluminum conductive circuit for back-contact photovoltaic modules as described above may be manufactured by the following method (see FIG. 5a to FIG. 5g):

(a) providing a substrate 4010 having a back side and a front side opposite to one another;

(b) providing an aluminum plate or foil 4001 having a back side and a front side opposite to one another, wherein the aluminum plate is made of aluminum or an aluminum alloy (see FIG. 5a);

(c) welding directly a plurality of conductive parts 4022b onto the front side of the aluminum plate 4001 in a certain pattern by ultrasonic welding with a frequency of 10-50 kHz and an amplitude of 8-50 μm, wherein each of the conductive parts 4022b is made of one or more metallic materials, and the contact area of the conductive part 4022b with the aluminum plate is 3-20 mm² (see FIG. 5b);

(d) laminating the aluminum plate 4001 onto the front side of the substrate 4010, wherein the back side of the aluminum plate 4001 is in contact with the front side of the substrate 4010 (see FIG. 5c);

(e) cutting out a certain pattern on the aluminum plate 4001 to form an aluminum conductive circuit 4011 (see FIG. 5d);

(f) providing a back insulation layer 4020 having a back side and a front side opposite to one another, laminating the back insulation layer onto the front side of the aluminum conductive circuit 4011 (see FIG. 5E), forming a plurality of through holes 4021 extending from the back side of the back insulation layer 4020 to the front side on the back insulation layer 4020, in which, the number and the arrangement pattern of the through holes 4021 being consistent with those of the conductive parts 4022b on the aluminum conductive circuit 4011 and the through holes 4021 being aligned with the conductive parts 4022b welded on the aluminum conductive circuit 4011 (see FIG. 5F); alternatively, providing a back insulation layer 4020 having a back side and a front side opposite to one another, forming a plurality of through holes 4021 extending from the back side to the front side of the back insulation layer 4020, in which, the number and the arrangement pattern of the through holes 4021 being consistent with those of the conductive parts 4022b on the aluminum conductive circuit 4011, and laminating the back insulation layer 4020 onto the front side of the aluminum conductive circuit 4011 in a manner of having the through holes 4021 aligned with the conductive parts 4022b welded on the aluminum conductive circuit 4011;

(g) filling the through holes 4021 with electrical bonding parts 4022a so as to fill the through holes full of the electrical bonding parts 4022a to form an integrated back sheet 4000a with the aluminum conductive circuit 4011, wherein the electrical bonding parts 4022a are adjacent to the front side of the back insulation layer 4020, and the conductive part 4022b and the electrical bonding part 4022a are complementary to each other in shape and form a combined conductive component 4022.

In practical production, the sequence of the steps as described above may be changed. For instance, the aluminum plate 4001 may be cut (step e) in advance of the ultrasonic welding (step c). The lamination between the aluminum conductive circuit 4011 and the substrate 4010 and that between the back insulation layer 4020 and the aluminum conductive circuit 4011 may be conducted simultaneously or separately.

Generally, the aluminum conductive circuit 4011 on which the conductive parts 4022b are welded shall be laminated with the substrate 4010 and/or the back insulation layer 4020 only after the conductive parts 4022b are welded onto the front side of the aluminum conductive circuit 4011 (the ultrasonic welding step). Apart from this, there are no further limitations with respect to the sequence of the steps.

Furthermore, the present invention also discloses a method for manufacturing the back-contact photovoltaic module 4000 comprising steps as follows:

(h) after manufacturing the integrated back sheet 4000a (FIG. 5g), stacking a back-contact photovoltaic cell 4030 having a front sunlight receiving side and a back side opposite to one another and a plurality of electric contacts 4031 (shown in FIG. 4) formed on the back side onto the integrated back sheet 4000a, on the aluminum conductive circuit 4011, having the electrical bonding parts 4022a in the through holes 4021 in direct contact with the electric contacts 4031 on the back side of the back-contact photovoltaic cell 4030 as shown in FIG. 4;

(i) stacking a front encapsulation layer 4040 onto the front sunlight receiving side of the back-contact photovoltaic cell 4030;

(j) stacking a transparent front panel 4050 onto the front encapsulation layer 4040;

(k) laminating the multilayer structure obtained from the above to obtain the back-contact photovoltaic module 4000 (see FIG. 4).

The technology of the present invention meets a need of manufacturers for back-contact photovoltaic modules. The integrated back sheet with the aluminum conductive circuit as well as the back-contact photovoltaic module manufactured by the method provided by the present invention can reduce considerably the consumption of conductive adhesive and copper thereby lowering significantly the manufacturing cost and meanwhile improving the efficiency of a back-contact photovoltaic module.

### EXAMPLES

The advantages of the present invention will be described in detail with the following examples; however, the present invention is not limited to the following examples.

The materials used in the photovoltaic module (photovoltaic component) of the present examples are as follows:

MWT Cell: 156 mm polycrystalline silicon metal wrap through (MWT) back-contact photovoltaic cell, purchased from Shanghai JA Solar PV Technology Co., Ltd.;

Glass Plate: 3.2 mm ultra clear glass, purchased from Henan Sikeda New Energy Co., Ltd.;

EVA Film-1: Revax™ ethylene-vinyl acetate copolymer (EVA) film with a thickness of 450 μm, purchased from Wenzhou RuiYang Photovoltaic Material Co., Ltd.;

EVA Film-2: EVA film with a thickness of 250 μm, obtained by hot-pressing of the EVA film-1 for 5 min at 100° C.;

PET Film: Melinex™ corona treated polyethylene terephthalate film (with a thickness of 188 μm; density: 1.40 g/cm³), purchased from DuPont Teijin Films (U.S.A.);

ECP-1 (Ethyleneacrylate Copolymer Resin): Bynel® 22E757 modified ethylene/acrylate copolymer resin purchased from E. I. du Pont de Nemours and Company;

ECP-2 (Ethylene Methacrylic Acid Copolymer Resin): Nucrel® 0910 ethylene methacrylic acid copolymer resin, purchased from E. I. du Pont de Nemours and Company;

PVF Film: Tedlar polyvinyl fluoride oriented film with a thickness of 38 μm, purchased from E. I. du Pont de Nemours and Company;

Polyurethane Adhesive: PP-5430 two-component polyurethane adhesive, purchased from Mitsui & Co., Ltd.;

Copper Foil-1: 35 μm-thick copper foil, purchased from Suzhou Fukuda Metal Co., Ltd.;

Copper Foil-2: 105 μm-thick copper foil, purchased from Suzhou Fukuda Metal Co., Ltd.;

Nickel-clad Copper Foil: 50 μm-thick copper foil plated with 500 nm-thick Ni on the surface, purchased from Chang Chun Group;

Aluminum Foil-1: 50 μm-thick aluminum foil, purchased from Hanpin (Kunshan) Electronic Co., Ltd.;

Aluminum Foil-2: 200 μm-thick aluminum foil, purchased from Foshan AZian Aluminum Distribution Co. Ltd.;

ECA-1 (Conductive Adhesive-1): Thermoset® MD-140 conductive adhesive with silver particles, purchased from LORD Corporation (U.S.A.);

ECA-2 (Conductive Adhesive-2): an elastomer mixture-based conductive adhesive with silver particles (final silver concentration: 78 wt. %) prepared by the following steps: premixing 16.5 g of ethylene/methyl acrylate copolymer (E/MA, containing 62 wt. % of methyl acrylate) and 16.5 g of ethylene-vinyl acetate copolymer (EVA, containing 33 wt. % of vinyl acetate, trade name: Elvax® PV1650, purchased from DuPont) with 0.4 g of peroxide (trade name: LQ-TBEC, purchased from Lanzhou Auxiliary Agent Plant, China), 0.3 g of silane coupling agent (trade name: KBM403, purchased from Shin-Etsu Chemical Co., Ltd.) and 0.12 g of antioxidant (trade name: Irganox™ MD1024, purchased from BASF (Germany)); and then banburying and mixing the obtained premixed substance together with 92 g of amorphous silver powder with a particle size of 3-5 μm (Kunming Noble Metal Electronic Materials Co., Ltd.) and 25 g of spherical silver powder with a particle size of 5.4-11 μm (DuPont, U.S.A.) for 10 minutes at 80° C. to obtain the ECA-2.

### Preparation of Substrate

The preparation of the substrate comprises the following steps: employing a 10 μm-thick polyurethane adhesive layer to adhere the PVF film to one side of the PET film; and then employing an extruding laminator manufactured by Davis Standard to extrude a mixture of ECP-1 resin and ECP-2 resin having a weight ratio of 1:1 onto the PET film to form a composite film bonding layer with a thickness of about 100 μm, thereby obtaining a substrate for use in the examples as described in the following paragraphs. The side having the composite film bonding layer is the front side adjacent to the conductive circuit.

### Test of Output Power of Back-Contact Photovoltaic Module

The output power of the back-contact photovoltaic module is measured by SPI-SUN Simulators 3500SLP solar simulator and PV module QA detector.

### Comparative Example 1

First, a back-contact photovoltaic module with a copper conductive circuit was prepared through the following steps: applying Copper Foil-1 onto the front side of the substrate by vacuum lamination; manually cutting the copper foil to form a copper conductive circuit in a predetermined pattern; die cutting the back insulation layer made of the EVA Film-1 to obtain a plurality of through holes with a diameter of 3 mm; aligning the through holes of the back insulation layer and laminating it onto the copper conductive circuit (for 2.5 minutes, at 65° C.); filling the conductive adhesive ECA-1 into the through holes of the back insulation layer; placing the MWT cell onto the front side of the back insulation layer; placing a front encapsulation layer made of another EVA Film-1 onto the front side of the MWT cell; placing a front panel made of the glass plate onto the other side of the front encapsulation layer; laminating the assembly obtained from above with a Meier ICOLAM™ 10/08 laminator (Meier Vakuumtechnik GmbH (Germany)) in a vacuum at 145° C. for 15 minutes to obtain the back-contact photovoltaic module with a copper conductive circuit. The output power test as described above indicated that the output power of the prepared back-contact photovoltaic module was 3.64 W.

### Comparative Example 2

A back-contact photovoltaic module with a copper conductive circuit was prepared according to the method described in Comparative Example 1. The difference is that, in Comparative Example 2, the back insulation layer was made of EVA Film-2, and the conductive adhesive filled in the through holes of the back insulation layer was ECA-2. The output power of the thus prepared back-contact photovoltaic module with the copper conductive circuit was 3.66 W.

### Comparative Example 3

A back-contact photovoltaic module with an aluminum conductive circuit was prepared according to the method described in Comparative Example 1. The difference is that, in Comparative Example 3, the copper conductive circuit was replaced by an aluminum conductive circuit made of Aluminum Foil-1, and each through hole of the back insulation layer was filled with a combined conductive component comprising a conductive part adjacent to the aluminum conductive circuit. The conductive part was a copper sheet (cut from the Copper Foil-2) having a diameter of 3 mm and a thickness of 105 μm. The conductive component also comprised an electrical bonding part made of Conductive Adhesive ECA-1 and the electrical bonding part was filled into the portion of the through hole which was not filled with the conductive part. The output power of the thus prepared back-contact photovoltaic module with an aluminum copper conductive circuit was 0.93 W.

### Example 1

The back-contact photovoltaic module with an aluminum conductive circuit of the present invention was prepared by the following method: cutting the Nickel-clad Copper Foil into a plurality of copper sheets having a thickness of 50 μm and a diameter of 3 mm and attaching the copper sheets, in a certain pattern, onto the Aluminum Foil-2 by ultrasonic welding with a frequency of 24 kHz and an amplitude of 20 μm; pressing Aluminum Foil-2 onto the front side of the substrate by vacuum lamination (with the side of the Aluminum Foil-2 welded with the copper sheets opposite to the substrate); manually cutting the Aluminum Foil-2 to form an aluminum conductive circuit in a predetermined pattern; die cutting the back insulation layer made of EVA Film-1 to form a plurality of through holes having a diameter of 3 mm; aligning the through holes of the back insulation layer with the copper sheets on the aluminum conductive circuit and laminating the back insulation layer onto the aluminum conductive circuit (for 2.5 minutes, at 65° C.); hot pressing and die cutting the conductive adhesive ECA-2 to obtain conductive adhesive gaskets having a thickness of 400 μm and a diameter of 2.5 mm, and placing the conductive gasket into the through hole (such that the copper piece and the conductive adhesive gasket formed a combined conductive component to fill the through hole of the back insulation layer, wherein the copper sheet adjacent to the aluminum conductive circuit served as the conductive part, and the conductive adhesive gasket served as the electrical bonding part); placing a MWT cell onto the front side of the back insulation layer; placing a front encapsulation layer made of another EVA Film-1 onto the front side of the MWT cell; placing a front panel made of the glass plate onto the other side of the front encapsulation layer; laminating the assembly obtained from above with Meier ICOLAM™ 10/08 laminator (Meier Vakuumtechnik GmbH (Germany)) in a vacuum at 145° C. for 15 minutes to obtain the back-contact photovoltaic module with the aluminum conductive circuit. The output power of thus prepared back-contact photovoltaic module was 3.58 W.

### Example 2

A back-contact photovoltaic module with an aluminum conductive circuit was prepared according to the method described in Example 1, except that, in Example 2, the aluminum conductive circuit was made of Aluminum Foil-1, the copper sheets having a thickness of 35 μm and a diameter of 3 mm welded (welding conditions: frequency: 20 kHz; amplitude: 12 μm) on the aluminum conductive circuit were cut from Copper Foil-1, and the portion of the through hole not filled with the copper sheet was filled with Conductive Adhesive ECA-1. The output power of thus prepared back-contact photovoltaic module with the aluminum conductive circuit was 3.70 W.

### CONCLUSION

The output power of the back-contact photovoltaic modules with the copper conductive circuit (Comparative Example 1 and Comparative Example 2) was 3.64 W or 3.66 W. Where the back-contact photovoltaic module with an aluminum conductive circuit was prepared by the traditional method for preparing the back-contact photovoltaic module with a copper conductive circuit (i.e. replacing the copper conductive circuit with an aluminum conductive circuit) (Comparative Example 3), the output power was decreased considerably to 0.93 W. Where the through hole of the back insulation layer was filled with the combined conductive component and the conductive part of the combined conductive component was welded onto an aluminum conductive circuit by ultrasonic welding, the output power of the prepared back-contact photovoltaic module with the aluminum conductive circuit (Example 1 and Example 2) was increased to 3.58 W or 3.70 W.

Some preferred embodiments of the present invention have been described and illustrated in detail in the paragraphs above; however, the present invention is not limited to these embodiments. In addition, many features, advantages, structure details and functions of the present invention are illustrated in the paragraphs above; however, it should be understood that the disclosure is just exemplary. Modifications to the details of the present invention, particularly to the shape, size and part arrangement, may be made to a full extent within the broad general meaning of the terms used in the appended claims without departing from the principle of the present invention.

What is claimed is:

1. An integrated back sheet with an aluminum conductive circuit for a back-contact photovoltaic module, comprising in sequence the following from the back to the front:
a substrate having a back side and a front side opposite to one another;
an aluminum conductive circuit provided on the front side of the substrate, the aluminum conductive circuit having a back side adjacent to the substrate and a front side facing away from the substrate; and
a back insulation layer adjacent to the aluminum conductive circuit, the back insulation layer having a back side adjacent to the aluminum conductive circuit and a front side facing away from the aluminum conductive circuit, and the back insulation layer being provided with a plurality of through holes extending from the back side to the front side of the back insulation layer and aligned with the conductive circuit;
wherein, each through hole is filled with a combined conductive component comprising an electrical bonding part and a conductive part complementary to the electrical bonding part in shape; the electrical bonding part is adjacent to the front side of the back insulation layer; the conductive part is formed of one or more metallic materials and welded directly onto the front side of the aluminum conductive circuit by ultrasonic welding with a frequency of 10-50 kHz and an amplitude of 8-50 μm;
and the conductive part is in contact with the front side of the aluminum conductive circuit; and
when the integrated back sheet is used in the manufacture of the back-contact photovoltaic module, the electrical bonding part of the combined conductive component is attached to an electric contact on the back side of a back-contact photovoltaic cell.

2. The integrated back sheet according to claim 1, wherein the contact area of the conductive part and the front side of the aluminum conductive circuit is 3-20 mm².

3. The integrated back sheet according to claim 1, wherein the one or more metallic materials are selected from the group of substance consisting of copper, tin, nickel, titanium, silver-plated copper, nickel-clad copper, copper-clad aluminum, tinned copper, gold-plated nickel, stainless steel, alloys thereof, and combinations thereof.

4. The integrated back sheet according to claim 1, wherein the conductive part of the combined conductive component accounts for 3-95% of the total volume of the combined conductive component.

5. The integrated back sheet according to claim 1, wherein the electrical bonding part is made of a conductive material comprised at least 5% by volume by a polymer material.

6. The integrated back sheet according to claim 5, wherein the electrical bonding part is made of a conductive polymer material.

7. The integrated back sheet according to claim 5, wherein the electrical bonding part is made of a conductive adhesive comprising a polymer material and conductive particles dispersed in the polymer material.

8. The integrated back sheet according to claim 7, wherein the conductive particles are selected from a group consisting of gold, silver, nickel, copper, aluminum, tin, zinc, titanium, bismuth, tungsten, lead, and alloys thereof.

9. The integrated back sheet according to claim 1, wherein the back insulation layer is formed of one or more layers of a polymer film or plate.

10. The integrated back sheet according to claim 9, wherein at least one layer of the back insulation layer is formed of a polymer composition comprising ethylene-vinyl acetate copolymer (EVA), an ionomer or poly(vinyl butyral) (PVB).

11. The integrated back sheet according to claim 1, wherein the thickness of the aluminum conductive circuit is 30-250 μm.

12. A back-contact photovoltaic module, comprising in sequence the following from the back to the front:
the integrated back sheet with the aluminum conductive circuit according to claim 1;
a back-contact photovoltaic cell having a front sunlight receiving side and a back side opposite to one another, and a plurality of electric contacts formed on the back side of the back-contact photovoltaic cell, the back side of the back-contact photovoltaic cell being adjacent to the back insulation layer of the integrated back sheet, and the plurality of electric contacts on the back side of the back-contact photovoltaic cell being aligned with the plurality of through holes of the back insulation layer and connected with the electrical bonding parts in the through holes;
a front encapsulation layer adjacent to the front side of the back-contact photovoltaic cell; and
a transparent front panel adjacent to the front encapsulation layer.

13. The back-contact photovoltaic module according to claim 12, wherein the back-contact photovoltaic cell is a metal wrap through (MWT) type photovoltaic cell.
